(19) United States
(12) Patent Application Publication
(10) Pub. No.: US 2018/0356724 A1
(43) Pub. Date: Dec. 13, 2018

(54) PHOTO-IMAGEABLE THIN FILMS WITH HIGH DIELECTRIC CONSTANTS

(71) Applicants: Dow Global Technologies LLC, Midland, MI (US); Rohm and Haas Electronic Materials Korea Ltd., Cheonan (KR)

(72) Inventors: Caroline Woelfle-Gupta, Midland, MI (US); Yuanqiao Rao, Berwyn, PA (US); Seok Han, Seoul (KR); William H. H. Woodward, Harbor Beach, MI (US)

(21) Appl. No.: 15/781,727

(22) PCT Filed: Dec. 6, 2016
(86) PCT No.: PCT/US16/65078

§ 371 Date: Jun. 6, 2018

Related U.S. Application Data
(60) Provisional application No. 62/268,538, filed on Dec. 17, 2015.

(51) Int. Cl. G03F 7/004; G03F 7/075

(52) U.S. Cl. CPC G03F 7/0047; G03F 7/0757

(57) ABSTRACT

A formulation for preparing a photo-imageable film; said formulation comprising: (a) a positive photoresist comprising a polysiloxane binder and a photo-active species; and (b) functionalized zirconium oxide nanoparticles.

### FIELD OF THE INVENTION

The present invention relates to a photo-imageable thin film with a high dielectric constant.

### BACKGROUND OF THE INVENTION

High dielectric constant thin films are of high interest for applications such as embedded capacitors, TFT passivation layers and gate dielectrics, in order to further miniaturize microelectronic components. One approach for obtaining a photo-imageable high dielectric constant thin film is to incorporate high dielectric constant nanoparticles in a photoresist. U.S. Pat. No. 7,630,043 discloses composite thin films based on a positive photoresist containing an acrylic polymer having alkali soluble units such as a carboxylic acid, and fine particles having a dielectric constant higher than 4. However, this reference does not disclose the use of a positive photoresist containing a polysiloxane binder. A different photoresist binder could provide different patterning characteristics and solvent resistance to a given photoresist formulation.

### SUMMARY OF THE INVENTION

The present invention provides a formulation for preparing a photo-imageable film; said formulation comprising: (a) a positive photoresist comprising a polysiloxane binder and a photo-active species; and (b) functionalized zirconium oxide nanoparticles.

### DETAILED DESCRIPTION OF THE INVENTION

Percentages are weight percentages (wt %) and temperatures are in ° C., unless specified otherwise. Operations were performed at room temperature (20-25° C.), unless specified otherwise. The term “nanoparticles” refers to particles having a diameter from 1 to 100 nm; i.e., at least 90% of the particles are in the indicated size range and the maximum peak height of the particle size distribution is within the range. Preferably, nanoparticles have an average diameter 75 nm or less; preferably 50 nm or less; preferably 25 nm or less; preferably 10 nm or less; preferably 7 nm or less. Preferably, the average diameter of the nanoparticles is 0.3 nm or more; preferably 1 nm or more. Particle sizes are determined by Dynamic Light Scattering (DLS). Preferably the breadth of the distribution of diameters of zirconia particles, as characterized by breadth parameter BP=(N75-N25), is 4 nm or less; preferably 3 nm or less;

preferably 2 nm or less. Preferably the breadth of the distribution of diameters of zirconia particles, as characterized by BP =(N75-N25), is 0.01 or more. It is useful to consider the quotient W as follows:

W=(N75−N25)/Dm

where Dm is the number-average diameter. Preferably W is 1.0 or less; more preferably 0.8 or less; more preferably 0.6 or less; more preferably 0.5 or less; more preferably 0.4 or less. Preferably W is 0.05 or more.

Preferably, the functionalized nanoparticles comprise zirconium oxide and one or more ligands, preferably ligands which have alkyl, heteroalkyl (e.g., poly(ethylene oxide)) or aryl groups having polar functionality; preferably carboxylic acid, alcohol, trichlorosilane, trialkoxysilane or mixed chloro/alkoxy silanes; preferably carboxylic acid. It is believed that the polar functionality bonds to the surface of the nanoparticle. Preferably, ligands have from one to twenty-five non-hydrogen atoms, preferably one to twenty, preferably three to twelve. Preferably, ligands comprise carbon, hydrogen and additional elements selected from the group consisting of oxygen, sulfur, nitrogen and silicon. Preferably alkyl groups are from C1-C18, preferably C2-C12, preferably C3-C8. Preferably, aryl groups are from C6-C12. Alkyl or aryl groups may be further functionalized with isocyanate, mercapto, glycidoxy or (meth)acryloyloxy groups. Preferably, alkoxy groups are from C1-C4, preferably methyl or ethyl. Among organosilanes, some suitable compounds are alkyltrialkoxysilanes, alkoxy(polyalkyleneoxy)alkyltrialkoxysilanes, substituted-alkyltrialkoxysilanes, phenyltrialkoxysilanes, and mixtures thereof. For example, some suitable oranosilanes are n-propyltrimethoxysilane, n-propyltriethoxysilane, n-octyltrimethoxysilane, n-octyltriethoxysilane, phenyltrimethoxysilane, 2-[methoxy(polyethyleneoxy)propyl]-trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-isocyanatopropyltriethoxysilane, 3-isocyanatopropyltrimethoxysilane, glycidoxypropyltrimethoxysilane, and mixtures thereof.

Among organoalcohols, preferred are alcohols or mixtures of alcohols of the formula R10OH, where R10 is an aliphatic group, an aromatic-substituted alkyl group, an aromatic group, or an alkylalkoxy group. More preferred organoalcohols are ethanol, propanol, butanol, hexanol, heptanol, octanol, dodecyl alcohol, octadecanol, benzyl alcohol, phenol, oleyl alcohol, triethylene glycol monomethyl ether, and mixtures thereof Among organocarboxylic acids, preferred are carboxylic acids of formula R11COOH, where R11 is an aliphatic group, an aromatic group, a polyalkoxy group, or a mixture thereof. Among organocarboxylic acids in which R11 is an aliphatic group, preferred aliphatic groups are methyl, propyl, octyl, oleyl, and mixtures thereof. Among organocarboxylic acids in which R11 is an aromatic group, the preferred aromatic group is C6H5. Preferably R11 is a polyalkoxy group. When R11 is a polyalkoxy group, R11 is a linear string of alkoxy units, where the alkyl group in each unit may be the same or different from the alkyl groups in other units. Among organocarboxylic acids in which R11 is a polyalkoxy group, preferred alkoxy units are methoxy, ethoxy, and combinations thereof. Functionalized nanoparticles are described, e.g., in US2013/0221279.

Preferably, the amount of functionaliied nanoparticles in the formulation (calculated on a solids basis for the entire formulation) is from 50 to 95 wt %; preferably at least 60 wt %, preferably at least 70 wt %, preferably at least 80 wt %, preferably at least 90 wt %; preferably no greater than 90 wt %.

Preferably, the photo active species comprised a photo acid compound (PAC). A PAC provides sensitivity to ultraviolet light. After exposure to ultraviolet light, the photo acid compound is changed from an insoluble state to a soluble state via the formation of indene carboxylic acid species by Wolff-rearrangement. Examples of photo-acid compounds can include (2-Diazo- 1-naphthone-5-sulfonyl chloride ester or (2-Diazo-1-naphthone-4-sulfonyl chloride ester with different potential ballasts such as for example 4′-[1-[4-[1-(4-hydorxyphenyl)-1-methylethyl]phenyl] ethylidene]bis[phenol].

### Formation of an Example PAC

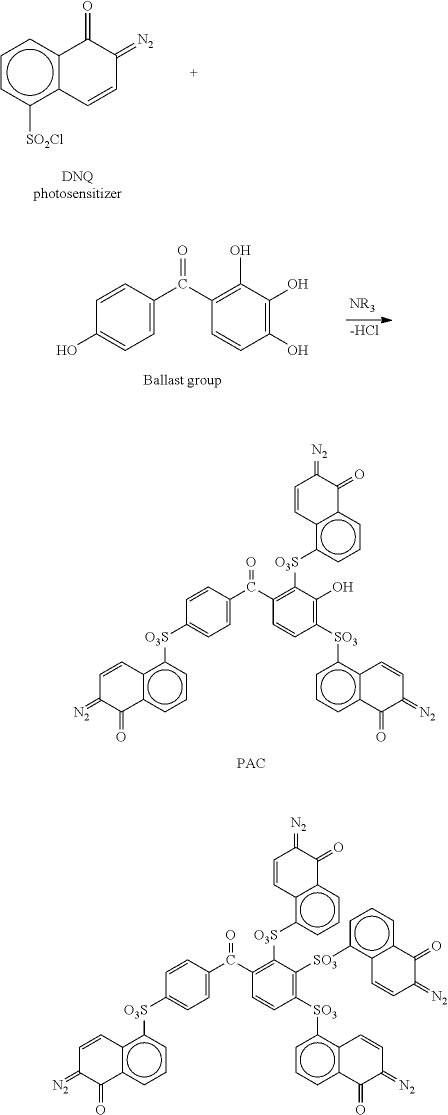

Photo-reaction of a general photo acid compound:

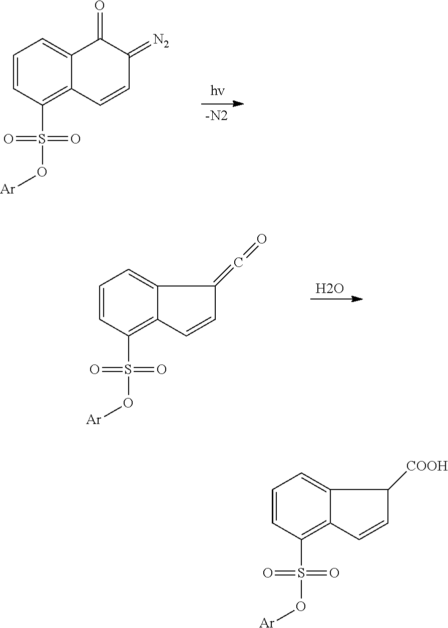

Preferably, the polysiloxane has weight average molecular weight (Mw) from 3,000 to 12,000 g/mole, preferably at least 4,500 g/mole, preferably at least 6,500 g/mole; preferably no greater than 8,500, preferably no greater than 10,000; all based on polystyrene equivalent molecular weight. Preferably, the polysiloxane comprises at least one of: C₁-C₁₈ alkyl groups, phenyl groups, (meth)acryloyl groups, vinyl groups and epoxy groups; preferably C₁-C₄ alkyl groups and phenyl groups.

Preferably, the film thickness is at least 50 nm, preferably at least 100 nm, preferably at least 500 nm, preferably at least 1000 nm; preferably no greater than 3000 nm, preferably no greater than 2000 nm, preferably no greater than 1500 nm. Preferably, the formulation is coated onto standard silicon wafers or Indium-Tin Oxide (ITO) coated glass slides.

### EXAMPLES

### Materials

Pixelligent PN zirconium oxide (ZrO2) functionalized nanoparticles with a particle size distribution ranging from 2 to 13 nm were purchased from Pixelligent Inc. These nanoparticles were synthesized via solvo-thermal synthesis, with a zirconium alkoxide based precursor. The potential zirconium alkoxide based precursor used may include zirconium (IV) isopropoxide isopropanol, zirconium (IV) ethoxide, zirconium (IV) n-propoxide, and zirconium (IV) n-butoxide. Different potential capping agents described in the text of this invention can be added to the nanoparticles via a cap exchange process. The developer MF-26A (2.38wt % tetramethyl ammonium hydroxoide) was provided by the Dow Electronic Materials group. The SOPX-LP1 broadband g-line and i-line positive photoresist was provided by the Dow Electronics Materials group. The composition of SOPX-LP1 is detailed in Table 1.

TABLE 1
Composition of the positive photoresist SOPX-LP1.

| Component | Trade Name | Description | wt % |
|---|---|---|---|
| Polysiloxane binder | CRSP-2000 | Phenylmethylsiloxane | 20.14 |
| Photo Acid | MIPHOTO | 2-Diazo-1-naphthone-5- | 2.76 |
| Compound | TPA523 | sulfonyl chloride ester | |
| | | with 4′-[1-[4-[1- | |
| | | (4-hydorxyphenyl)-1- | |
| | | methylethyl]phenyl] | |
| | | ethylidene]bis[phenol] | |
| Surfactant | TORAY | Dimethicone polyether block | 0.05 |
| | FZ2122 | copolymer | |
| Solvent | PGMEA | Propylene glycol methyl ether | 77.05 |
| | | acetate | |

### Thin Film Preparation

Solutions were prepared containing different ratios of Pixelligent PN (Pix-PN) type nanoparticles mixed with the positive photoresist SOPX-LP1. A spin curve was developed for each of the thin film compositions used, and spin speeds were adjusted accordingly to obtain a target thin film thicknesses of 1000 nm for each composition.

### Dielectric Constant Characterization

Four 50 nm thick gold electrodes 3mm in diameter were deposited on each nanoparticle-photoresist thin films. The ITO was contacted with an alligator clip, and the gold electrodes with a gold wire to be able to apply a frequency sweep to the sample. The capacitance was measured for each sample, and the dielectric constant determined via Equation 1 with C being the capacitance, a the dielectric constant, ε0 the vacuum dielectric permittivity, A the area of the electrode, and d the thickness of the film.

C=εrε0.A/d Equation 1

### Photo-Imageability (Flood Exposure)

The SOPX-LP1 based thin films were subjected to a soft bake at 100° C. for 90 s. The films were exposed to UV radiation via the use of an Oriel Research arc lamp source housing a 1000 W mercury lamp fitted with a dichroic beam turning mirror designed for high reflectance and polarization insensitivity over a 350 to 450 primary spectral range. The energy density of the UV radiation was 60 mJ/cm2. After post bake, the coated wafers were dipped into a petri dish containing MF-26A for 80 s. Thickness of the films after each dipping time was determined via an M-2000 Woollam spectroscopic ellipsometer.

### Nanoparticle Dispersion in the Film

Nanoparticle-photoresist thin film samples spin-coated on Kapton substrates approximately 2.5 cm2 each were used. A 1 mm×2mm piece of film was extracted from the corner of the spin-coated films with a razor blade. This piece was mounted in a chuck so that the thickening of the layer (the drip at the corner) could be sectioned into without having to include the Kapton substrate. A Leica UC6 ultramicrotome was operated at room temperature. The sectioning thickness was set to 45 nm at a cutting rate of 0.6 cuts/s. A diamond wet knife was used for all sectioning. Sections were floated on a water surface and collected onto 150 mesh formvar-coated copper grids and dried in the open atmosphere at ambient temperature. A JEOL transmission electron microscope was operated at 100 kV of accelerating voltage with a spot size of 3. Both the condenser and objective apertures were set to large. The microscope was controlled by Gatan Digital Micrograph v3.10 software. Image data was collected using a Gatan Multiscan 794 CCD camera. Adobe Photoshop v9.0 was used to post-process all images.

### Thin Films Thickness Measurements

The coatings on the glass slides were scratched to expose the glass surface for measuring the coating thicknesses. To verify the accuracy of the measurements and ensure that the glass substrate was not damaged by the stylus, the scratching was also done on the glass without coating, and it was observed that no damage was created when a similar force was applied. The surface profile was obtained on a Dektak 150 stylus profilometer. The thickness was measured as the height between surface and the flat bottom of the scratch. For each sample at least 8 measurements were done at 2 different scratches.

### Dielectric Constant Results

Table 2 lists the permittivities measured at 1.15 MHz of several thin films made of different amounts of Pixelligent PN nanoparticles mixed with the SOPX-LP1 positive photoresist, as a function of weight percent of nanoparticles incorporated in the photoresist. The permittivity obtained was as high as 11.28 for the thin films containing 93.93 wt % of nanoparticles present in the corresponding thin film. The permittivity was still higher than the Dow customer CTQ of 6.5 for thin films containing a 67.59 wt % of nanoparticles.

TABLE 2
Permittivity measured at 1.15 MHz of SOPX-LP1-nanoparticle thin films,
as a function of the weight percent of nanoparticles incorporated
in the photoresist and a target film thickness of 1000 nm.

| | | | | | Permit- | |
|---|---|---|---|---|---|---|
| | Pix-PN | | | | tivity | |
| | solution in | SOPX- | Wt % | Vol % | (1000 nm | |
| | PGMEA | LP1 | of nano- | of nano- | thickness | Standard |
| Sample | (g) | (g) | particles | particles | target) | deviation |
| Pix-pt-1 | 1.998 | 0.2572 | 93.93 | 74.44 | 11.28 | 0.6286 |
| Pix-pt-2 | 2.002 | 0.5028 | 89.68 | 62.09 | 10.51 | 0.6257 |
| Pix-pt-3 | 2.0216 | 1.0035 | 82.37 | 46.81 | 9.72 | 0.5074 |
| Pix-pt-4 | 1.9973 | 1.9993 | 72.39 | 33.06 | 7.62 | 0.3249 |
| Pix-pt-5 | 1.9947 | 2.9925 | 67.59 | 28.2 | 6.96 | 0.1050 |
| Pix-pt-6 | 1.9988 | 6.0127 | 60.05 | 22.07 | 5.76 | 0.2801 |
| SOPX- | NA | NA | NA | NA | 4.54 | 0.3910 |
| LP1 | | | | | | |

### Photoimageability of the Composite Thin Films

Table 3 shows the thicknesses of the SOPX-LP1 based thin films before and after experiencing a soft bake at 100° C. for 90 s, a UV exposure at a 60 mJ/cm2 energy density, and 80 s dip in MF-26A (2.38wt % TMAH). All the thin films were removed after 80 s in the developer, independently of the amount of nanoparticles present in the film.

TABLE 3
Thickness of the SOPX-LP1 nanoparticle thin films
before and after experiencing developing conditions
for an initial target film thickness of 1000 nm.

| | Thickness | UV Exposure | UV exposure | Thickness- 80 s |
|---|---|---|---|---|
| Sample | (nm) | (mJ/cm2) | time (s) | MF-26A (nm) |
| Pix-pt-1 | 1056.43 | 60 | 38 | 2.58 |
| Pix-pt-2 | 1057.69 | 60 | 38 | 2.42 |
| Pix-pt-3 | 1007.33 | 60 | 38 | 2.46 |
| Pix-pt-4 | 922.85 | 60 | 38 | 2.03 |
| Pix-pt-5 | 984.26 | 60 | 38 | 2.55 |
| Pix-pt-6 | 972.9 | 60 | 38 | 2.44 |
| SOPX- | 1000.67 | 60 | 38 | 5.02 |
| LP1 | | | | |

### Transmittance

Photomicrographs of the dispersion of ZrO2 functionalized nanoparticles in a positive photoresist SOPX-LP1 thin film containing 67.6 wt % of nanoparticles showed that the nanoparticles were very well dispersed in the photoresist, with no signs of nanoparticle agglomeration present. Transmittance of a PNLK-0531 thin film containing 92.8 wt % of Pix-PN nanoparticles was approximately 91% at 400 nm, which is higher than the 90% CTQ required by the customers. Transmittance was above 90% throughout almost the entire visible region.

1. A formulation for preparing a photo-imageable film; said formulation comprising: (a) a positive photoresist comprising a polysiloxane binder and a photo-active species; and (b) functionalized zirconium oxide nanoparticles.

2. The formulation of claim 1 in which the polysiloxane comprises at least one of C1-C4 alkyl groups and phenyl groups.

3. The formulation of claim 2 in which the functionalized zirconium oxide nanoparticles have an average diameter from 0.3 nm to 50 nm.

4. The formulation of claim 3 in which the functionalized zirconium oxide nanoparticles comprise ligands which have carboxylic acid, alcohol, trichlorosilane, trialkoxysilane or mixed chloro/alkoxy silane functionality.

5. The formulation of claim 4 in which the ligands have from one to twenty non-hydrogen atoms.

6. The formulation of claim 5 in which the amount of functionalized nanoparticles in the formulation, calculated on a solids basis for the entire formulation, is from 50 to 95 wt %.

7. The formulation of claim 6 in which the polysiloxane has weight average molecular weight from 3,000 to 12,000.
